(19) United States
(12) Patent Application Publication
(10) Pub. No.: US 2026/0114222 A1
(43) Pub. Date: Apr. 23, 2026

(54) SEMICONDUCTOR EQUIPMENT CONTROLLING SYSTEM AND OPERATING METHOD THEREOF

(71) Applicant: SAMSUNG ELECTRONICS CO., LTD., Suwon-si (KR)

(72) Inventors: Do-Young KIM, Suwon-si (KR); Euiseok KUM, Suwon-si (KR); Junseok LEE, Suwon-si (KR); Hae Yong JUNG, Suwon-si (KR); Yohwan JOO, Suwon-si (KR)

(73) Assignee: SAMSUNG ELECTRONICS CO., LTD., Suwon-si (KR)

(21) Appl. No.: 19/184,260

(22) Filed: Apr. 21, 2025

(30) Foreign Application Priority Data
Oct. 22, 2024 (KR) 10-2024-0144910

(51) Int. Cl. H01L 21/67; G05B 13/02; G05B 13/04; G05B 19/418

(52) U.S. Cl. CPC H10P 72/0604; G05B 13/027; G05B 13/041; G05B 19/4183; G05B 19/41865; G05B 19/41885; G05B 2219/45031

(57) ABSTRACT

A semiconductor equipment controlling system includes a scheduling algorithm selector configured to receive status data indicating a status of the equipment. If the status data is not included in training data for training a learning-based scheduling module, a first enable signal is generated. If the status data is included in the training data, a second enable signal is generated. A rule-based scheduling algorithm determines a first schedule corresponding to the status data based on a predetermined scheduling rule in response to receiving the first enable signal. The learning-based scheduling module determines a second schedule corresponding to the status data using a first neural network model in response to receiving the second enable signal. A hardware layer generates a hardware command for controlling the equipment based on the first schedule if the first enable signal is generated and based on the second schedule if the second enable signal is generated.

### CROSS-REFERENCE TO RELATED APPLICATION

This application claims priority to and the benefit of Korean Patent Application No. 10-2024-0144910 filed in the Korean Intellectual Property Office on Oct. 22, 2024, the entire contents of which are incorporated herein by reference.

### TECHNICAL FIELD

The present disclosure relates to a semiconductor equipment controlling system and an operating method thereof.

### BACKGROUND

Semiconductor manufacturing process management is the management of a series of processes from raw materials to the completion of the final product, and determines the task order, required materials, and time for the respective processes. In a semiconductor factory, various types of equipment are arranged according to the processes, and an overhead hoist transport (OHT) such as a conveyor is installed between the equipment so when a process is completed, it is designed to move a wafer to the next equipment to proceed with the next stage of the process. Additionally, multiple pieces of equipment may share and process the same or similar processes. In a manufacturing line like this, determination of an optimized schedule for wafers processed within the equipment to manage the process or task improves factory efficiency.

### SUMMARY

The present disclosure provides a semiconductor equipment controlling system for determining optimized schedules, and an operating method thereof.

Some embodiments provide a semiconductor equipment controlling system including: a scheduling algorithm selector configured to receive status data indicating a status of equipment, determine whether the status data is included in training data, generate a first enable signal in response to the status data not being included in the training data, and generate a second enable signal in response to the status data being included in the training data; a rule-based scheduling algorithm configured to determine a first schedule corresponding to the status data based on a predetermined scheduling rule in response to receiving the first enable signal; a learning-based scheduling module including a first neural network model, configured to determine a second schedule corresponding to the status data by the first neural network model in response to receiving the second enable signal; and a hardware layer configured to generate a hardware command for controlling the equipment based on a final determined schedule, wherein the final determined schedule is the first schedule if the first enable signal is generated and the final determined schedule is the second schedule if the second enable signal is generated.

Some embodiments provide a semiconductor equipment controlling system including: a rule-based scheduling algorithm configured to receive status data indicating a status of equipment, and generate a first scheduling command corresponding to the status data based on a predetermined scheduling rule; a learning-based scheduling module configured to receive the status data and generate a second scheduling command corresponding to the status data using a trained first neural network model; a scheduling algorithm selector configured to determine whether the status data is included in training data, determine the first scheduling command as a final scheduling command in response to the status data not being included in the training data, and determine the second scheduling command as the final scheduling command in response to the status data being included in the training data; and a hardware layer configured to convert the final scheduling command into a hardware command for controlling the equipment.

Some embodiments provide a semiconductor equipment controlling system including: equipment configured to perform a task for at least one wafer and generate status data indicating a status while performing the task; an equipment control device configured to receive the status data, determine a final schedule based on whether the status data are included in training data, and control the equipment based on the final schedule, wherein the final schedule includes a first schedule determined based on a predetermined scheduling rule in response to the status data not being included in the training data, and the final schedule includes a second schedule determined using a trained first neural network model in response to the status data being included in the training data; and a scheduling learning device including a second neural network model, the training data, history data, and a third schedule corresponding to the training data, wherein the scheduling learning device is configured to generate an optimized scheduling model by training the second neural network model based on the training data and the history data.

### BRIEF DESCRIPTION OF THE DRAWINGS

FIG. 1 shows a semiconductor equipment controlling system according to an embodiment.

FIG. 2 shows a semiconductor equipment control device according to an embodiment.

FIG. 3 shows a semiconductor equipment according to an embodiment.

FIG. 4 shows an operation of a semiconductor equipment controlling system according to an embodiment.

FIG. 5 shows a semiconductor equipment control device according to an embodiment.

FIG. 6 shows an operation of a semiconductor equipment controlling system according to an embodiment.

FIG. 7 shows an example of a computing device for implementing a semiconductor equipment controlling system according to an embodiment.

### DETAILED DESCRIPTION

In the following detailed description, only certain embodiments of the present disclosure have been shown and described, simply by way of illustration. As those skilled in the art would realize, the described embodiments may be modified in various different ways, all without departing from the scope of the present disclosure.

Accordingly, the drawings and description are to be regarded as illustrative in nature and not restrictive, and like reference numerals designate like elements throughout the specification. In the flowcharts described with reference to the drawings in this specification, the operation order may be changed, various operations may be merged, certain operations may be divided, and certain operations may not be performed.

An expression recited in the singular may be construed as singular or plural unless the expression “one”, “single”, etc., is used. Terms including ordinal numbers such as first, second, and the like, will be used to describe various components, and are not to be interpreted as limiting these components. The terms may be used to differentiate one component from other components.

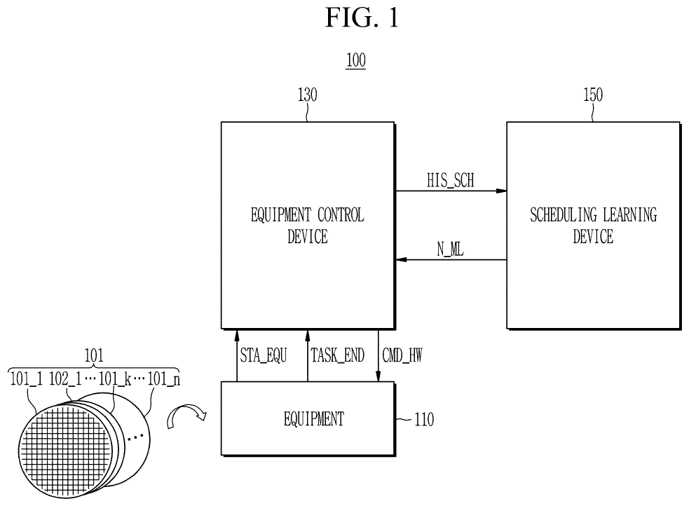

Referring to FIG. 1, a semiconductor equipment controlling system 100 may include equipment 110, an equipment control device 130, and a scheduling learning device 150.

The equipment 110 may perform tasks on wafers 101_1, 101_2, . . . , 101_k, . . . , 101_n based on control of the equipment control device 130. In an embodiment, the equipment 110 may be arbitrary equipment having a cluster platform. For example, an automated logistics system (e.g., an overhead hoist transport (OHT) system) may be connected to producing equipment in a cluster form, and the equipment 110 may efficiently manage movement of materials between the processes. For example, the equipment 110 may include at least one chamber and at least one transferring robot.

The equipment 110 may generate status data (STA_EQU) indicating a status of the equipment 110 while performing a task. The status data (STA_EQU) may include data on the equipment 110 and the wafers 101 while performing a task on the wafers 101. For example, the status data (STA_EQU) may include hardware data indicating statuses of parts (e.g., a chamber) in the equipment 110, an operation of the equipment 110, etc. The status data (STA_EQU) may include wafer status data (e.g., unprocessed wafers or processed wafers) indicating processed states of the respective wafers 101. The status data (STA_EQU) may include task data including task scenarios applied to the respective wafers 101. The equipment 110 may transmit the status data (STA_EQU) to the equipment control device 130 periodically or continuously.

In an embodiment, the equipment 110 may receive a hardware command (CMD_HW) from the equipment control device 130. The equipment 110 may perform the task indicated by the hardware command (CMD_HW). The hardware command (CMD_HW) may control operations of the chambers in the equipment 110 and operational times of the chambers.

In an embodiment, the equipment 110 may generate a task end signal (TASK_END) when execution of the task that corresponds to the hardware command (CMD_HW) indicated by the equipment control device 130 ends. The equipment 110 may transmit the task end signal (TASK_END) to the equipment control device 130 corresponding to the hardware command (CMD_HW). In an embodiment, the equipment 110 may generate the task end signal (TASK_END) when a physical and/or logical change is generated by the equipment 110. For example, the equipment 110 may generate the task end signal (TASK_END) when a new wafer is supplied or the equipment 110 generates errors.

The equipment control device 130 may be connected to the equipment 110 in a wired or wireless way.

The equipment control device 130 may receive the status data (STA_EQU) and the task end signal (TASK_END) from the equipment 110. In an embodiment, the equipment control device 130 may receive the status data (STA_EQU) from the equipment 110 periodically or continuously.

The equipment control device 130 may generate a schedule for controlling the equipment 110. The schedule may include data indicating a series of operations on the wafers 101 to be performed by the equipment 110.

In an embodiment, the equipment control device 130 may determine an optimized schedule based on the status data (STA_EQU) corresponding to receiving the task end signal (TASK_END). The present disclosure is not limited thereto, and the equipment control device 130 may determine the optimized schedule based on the status data (STA_EQU) for a predetermined time period.

In an embodiment, the equipment control device 130 may store a scheduling rule for indicating a predetermined schedule corresponding to arbitrary status data of the equipment 110. The equipment control device 130 may determine the schedule that corresponds to the current status data (STA_EQU) based on the scheduling rule. The equipment control device 130 may generate the determined schedule as a final schedule.

In an embodiment, the equipment control device 130 may include a neural network model. The neural network model may be trained based on predetermined training data. For example, the neural network model may be trained to output an optimized schedule for the equipment 110 corresponding to the input of the status data (STA_EQU) of the equipment 110. For example, the neural network model may determine the schedule indicating a series of operations with a highest yield or productivity of wafers from among actions executed by the equipment 110 having current status data (STA_EQU) as the optimized schedule. For example, productivity may indicate the number of wafers to be processed by the equipment 110 per unit time. The equipment control device 130 may determine the optimized schedule that corresponds to the status data (STA_EQU) based on the neural network model. The equipment control device 130 may generate the determined optimized schedule as the final schedule.

In an embodiment, the equipment control device 130 may generate a hardware command (CMD_HW) for controlling the equipment 110 to perform the tasks that correspond to the final schedule. The hardware command (CMD_HW) may control the respective parts of the equipment 110. For example, the hardware command (CMD_HW) may include information on target positions to which the wafers 101 are moved, moving times of the wafers 101, and times at which the tasks are performed for the wafers 101.

The equipment control device 130 may generate history data (HIS_SCH). The history data (HIS_SCH) may include information on the final schedule determined by the equipment control device 130 corresponding to the status data (STA_EQU) based on the scheduling rule. That is, the history data (HIS_SCH) may include status data (STA_EQU) that are not used to train the neural network model in the equipment control device 130 and the corresponding schedule in the scheduling rule.

The scheduling learning device 150 may store at least one neural network model and training data set. The neural network model may include layers, and the layers may be connected by operations to which weights are applied. The layers including operations may include a convolution layer for performing a convolution operation, a pooling layer for performing a down-sampling operation, an unpooling layer (UL) for performing an up-sampling operation, and a deconvolution layer (DL) for performing a deconvolution operation.

The neural network model may perform training according to various training methods such as deep learning or machine learning. For example, the scheduling learning device 150 may generate an optimized scheduling model by training the neural network model through unsupervised learning and/or supervised learning. Upon receiving the status data, the optimized scheduling model may output the optimized schedule that corresponds to the status data using layers, nodes, and weights.

In an embodiment, the scheduling learning device 150 may generate the optimized scheduling model by performing supervised learning on the neural network model based on the training data set. The training data set may include a portion of the status data (STA_EQU) and label data determined as training data. The label data may include a schedule that corresponds to the corresponding training data. The training data may be a portion of status data included in the scheduling rule. For example, the training data may be status data indicating a case when the equipment 110 is normally operated. For example, the training data may be status data indicating that all chambers in the equipment 110 are normally operated, the target wafer is an unprocessed wafer, and a first task is performed on the target wafer. That is, the scheduling learning device 150 may train the neural network model so that the neural network model may output the optimized schedule based on the received status data (STA_EQU).

In an embodiment, the scheduling learning device 150 may perform unsupervised learning on the neural network model and may update the optimized scheduling model.

In an embodiment, the scheduling learning device 150 may include a simulation module for determining the optimized schedule. The simulation module may generate candidate schedules performed by the equipment 110 based on the status data (STA_EQU). The simulation module may store information on characteristics of the equipment 110. For example, the simulation module may store information on driving methods of the equipment 110, driving ranges, and the characteristics of processing targets. The simulation module may simulate the operation of the equipment 110. The scheduling learning device 150 may control the simulation module to perform candidate schedules based on information on the characteristics of the equipment 110 and may deduce the yield or productivity of the respective candidate schedules. The scheduling learning device 150 may determine the schedule with a highest yield or productivity of wafers from among the candidate schedules as the optimized schedule based on the results from the simulation module.

In an embodiment, the scheduling learning device 150 may receive the history data (HIS_SCH) from the equipment control device 130. The scheduling learning device 150 may update the optimized scheduling model by performing unsupervised learning on the history data (HIS_SCH).

The scheduling learning device 150 may transmit the updated model data (N_ML) to the equipment control device 130. In an embodiment, the scheduling learning device 150 may periodically transmit the updated model data (N_ML) to the equipment control device 130. In an embodiment, the scheduling learning device 150 may transmit the updated model data (N_ML) having learned the history data (HIS_SCH) to the equipment control device 130 in response to receiving the history data (HIS_SCH) from the equipment control device 130.

For example, the scheduling learning device 150 may deduce the optimized schedule corresponding to the status data from among the history data (HIS_SCH) through the simulation module. For example, the history data (HIS_SCH) may include first status data and a first schedule predetermined based on the scheduling rule corresponding to the first status data. The scheduling learning device 150 may determine a second candidate schedule with the highest yield or productivity of wafers from among the candidate schedules that correspond to the first status data as the optimized schedule through the simulation module. The scheduling learning device 150 may train the neural network model to output the second candidate schedule corresponding to the first status data. The scheduling learning device 150 may train the neural network model based on the history data (HIS_SCH) and the updated model data (N_ML).

In FIG. 1, the scheduling learning device 150 is shown to be separated from the equipment control device 130, but the present disclosure is not limited thereto, and the equipment control device 130 may include the scheduling learning device 150.

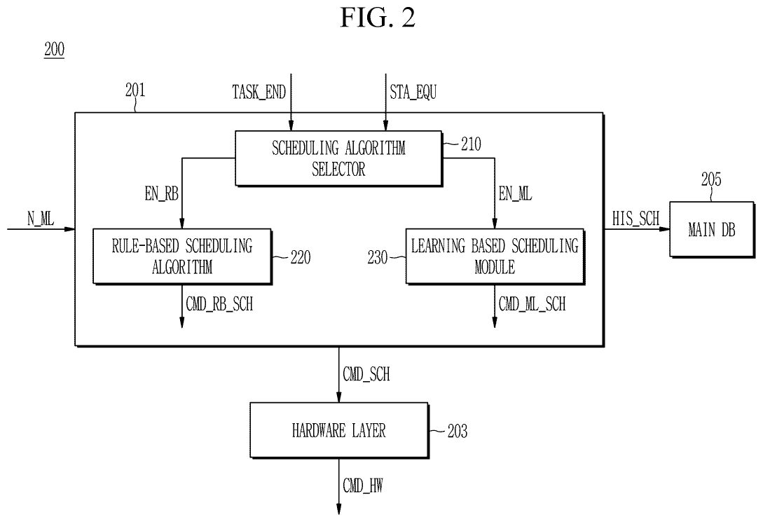

Referring to FIG. 2, an equipment control device 200 may include a scheduling layer 201, a hardware layer 203, and a main database 205.

The scheduling layer 201 may determine the final schedule based on the status data (STA_EQU). In an embodiment, the scheduling layer 201 may determine the final schedule in response to receiving the task end signal (TASK_END). The scheduling layer 201 may generate a final scheduling command (CMD_SCH) based on the final schedule. The scheduling layer 201 may transmit the final scheduling command (CMD_SCH) to the hardware layer 203.

The scheduling layer 201 may include a scheduling algorithm selector 210, a rule-based scheduling algorithm 220, and a learning-based scheduling module 230.

The scheduling algorithm selector 210 may determine whether the status data (STA_EQU) are included in the training data. The training data may be status data for training the learning-based scheduling module 230. In an embodiment, the scheduling algorithm selector 210 may receive the training data prestored in the main database 205. In some embodiments, the training data may be prestored in the scheduling algorithm selector 210.

In an embodiment, when the scheduling algorithm selector 210 determines that the status data (STA_EQU) are not included in the training data, that is, when the status data (STA_EQU) are determined to be unlearned data, the scheduling algorithm selector 210 may generate a first enable signal (EN_RB). The first enable signal (EN_RB) may enable the rule-based scheduling algorithm 220. The scheduling algorithm selector 210 may transmit the first enable signal (EN_RB) and the status data (STA_EQU) to the rule-based scheduling algorithm 220.

In an embodiment, when the scheduling algorithm selector 210 determines that the status data (STA_EQU) are included in the training data, the scheduling algorithm selector 210 may generate a second enable signal (EN_ML). The second enable signal (EN_ML) may enable the learning-based scheduling module 230. The scheduling algorithm selector 210 may transmit the second enable signal (EN_ML) and the status data (STA_EQU) to the learning-based scheduling module 230.

The rule-based scheduling algorithm 220 may determine the schedule in response to receiving the first enable signal (EN_RB). The rule-based scheduling algorithm 220 may determine the schedule to be performed by the equipment 110 based on a predetermined scheduling rule. For example, the rule-based scheduling algorithm 220 may determine the schedule that corresponds to the status data (STA_EQU) transmitted from the scheduling algorithm selector 210 based on the scheduling rule. The rule-based scheduling algorithm 220 may generate a first scheduling command (CMD_RB_SCH) that corresponds to the determined schedule.

In an embodiment, the scheduling rule may include information on arbitrary first status data and schedules that respectively correspond to the arbitrary first status data. The scheduling rule may include information on the schedule that corresponds to the first status data indicating the case that the equipment 110 is abnormally operated. For example, the scheduling rule may include information on the schedule to be executed by the equipment 110 corresponding to the first status data indicating the case in which a first chamber from among the chambers in the scheduling equipment 110 is abnormally operated, the target wafer is an unprocessed wafer, and a first task is performed on the target wafer. The scheduling rule may include the schedule for preventing an abnormal operation when the equipment 110 is abnormally operated. In an embodiment, the scheduling rule may be set based on experiences and knowledge of the user operating the equipment 110.

The rule-based scheduling algorithm 220 may generate history data (HIS_SCH). The history data (HIS_SCH) may include information on the unlearned data processed by the rule-based scheduling algorithm 220. In an embodiment, the history data (HIS_SCH) may include unlearned data received by the equipment control device 200 and the schedule determined by the rule-based scheduling algorithm 220 corresponding to the unlearned data. For example, the history data (HIS_SCH) may include status data (STA_EQU) and a first scheduling command (CMD_RB_SCH) corresponding to the status data (STA_EQU). The rule-based scheduling algorithm 220 may transmit the history data (HIS_SCH) to the main database 205.

The learning-based scheduling module 230 may determine the schedule in response to receiving the second enable signal (EN_ML). The learning-based scheduling module 230 may include a first neural network model trained by the scheduling learning device 150. The learning-based scheduling module 230 may determine the optimized schedule that corresponds to the status data (STA_EQU) using the trained first neural network model. For example, the learning-based scheduling module 230 may determine the optimized schedule using the first neural network model by inputting the status data (STA_EQU) into the first neural network model and obtaining the optimized schedule as output. The learning-based scheduling module 230 may generate a second scheduling command (CMD_ML_SCH) that corresponds to the optimized schedule.

In an embodiment, the learning-based scheduling module 230 may receive the updated model data (N_ML) from the scheduling learning device 150. The updated model data (N_ML) may include data on the optimized scheduling model learned by the scheduling learning device 150 based on the history data (HIS_SCH). For example, the updated model data (N_ML) may include information on the unlearned data included in the history data (HIS_SCH) and the optimized schedule that corresponds to the unlearned data. The learning-based scheduling module 230 may update the first neural network model based on the updated model data (N_ML). The learning-based scheduling module 230 may determine the optimized schedule that corresponds to the status data (STA_EQU) based on the updated first neural network model.

The main database 205 may store data with which the equipment control device 200 controls the equipment 110. In an embodiment, the main database 205 may store the history data (HIS_SCH). The rule-based scheduling algorithm 220 may transmit the history data (HIS_SCH) stored in the main database 205 to the scheduling learning device 150. In an embodiment, when receiving the updated model data (N_ML), the learning-based scheduling module 230 may store the status data included in the updated model data (N_ML) in the main database 205 as the training data.

In an embodiment, main database 205 may include a permanent mass storage device such as a random access memory (RAM), a read only memory (ROM), or a disk drive.

The hardware layer 203 may receive the final scheduling command (CMD_SCH) from the scheduling layer 201, and may convert the final scheduling command (CMD_SCH) into the hardware command (CMD_HW). The hardware command (CMD_HW) may control the respective parts of the equipment 110. For example, the hardware command (CMD_HW) may include commands for controlling chambers or an arm of a transferring robot in the equipment 110. The hardware layer 203 may pre-store the hardware command (CMD_HW) that corresponds to the final scheduling command (CMD_SCH). The hardware layer 203 may control the equipment 110 through the hardware command (CMD_HW).

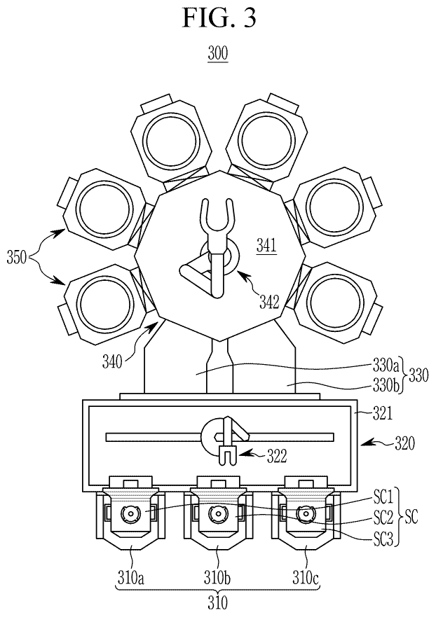

Referring to FIG. 3, the equipment 300 may include a load port module 310, an index module 320, a load lock chamber 330, a transfer module 340, and a process chamber 350.

The equipment 300 is a system for processing a semiconductor substrate using an etching process, a cleaning process, a deposition process, etc. The equipment 300 is shown to include multiple process chambers 350. The present disclosure should not be understood to be limited thereto, and the equipment 300 may include one process chamber. The process chambers 350 may be the same-type process chambers, and without being limited to, they may be different types of process chambers.

The load port module 310 allows a container SC in which semiconductor substrates are mounted to be appropriately disposed. For example, the container SC may be a front opening unified pod (FOUP).

The container SC may be loaded or unloaded on/from the load port module 310. The semiconductor substrate received in the container SC may be loaded or unloaded in the load port module 310.

When the container SC is loaded or unloaded, a container carrying device may load or unload the container SC on/from the load port module 310. For example, as the container SC taken by the container carrying device is disposed on the load port module 310, the container SC may be loaded on the load port module 310. The container carrying device may take the container SC disposed on the load port module 310 to unload the container SC from the load port module 310. For example, the container carrying device may be the overhead hoist transporter (OHT).

When the semiconductor substrate is loaded or unloaded, a first transferring robot 322 may load or unload the semiconductor substrate in the container SC in which the load port module 310 is disposed. In the case of unloading the semiconductor substrate, when the container SC is disposed on the load port module 310, the first transferring robot 322 may approach the load port module 310 and may unload the semiconductor substrate from the container SC. In the case of loading the semiconductor substrate, when the process for the semiconductor substrate in the process chamber 350 ends, the first transferring robot 322 may unload the semiconductor substrate from the load lock chamber 330, and may load the semiconductor substrate in the container SC.

Multiple load port modules 310 may be arranged at a front side of the index module 320. For example, three load port modules such as a first load port module 310a, a second load port module 310b, and a third load port module 310c may be arranged at the front side of the index module 320.

When the load port modules 310 are arranged at the front side of the index module 320, the container SC disposed on the respective load port modules may load different types of goods. For example, when the first load port module 310a, the second load port module 310b, and the third load port module 310c are arranged at the front side of the index module 320, the first container SC1 disposed on the first load port module 310a may load a wafer-type sensor, the second container SC2 disposed on the second load port module 310b may load a semiconductor substrate, that is, a wafer, and the third container SC3 disposed on the third load port module 310c may load expendable parts such as a focus ring or an edge ring.

The index module 320 may be arranged between the load port module 310 and the load lock chamber 330. The index module 320 may be provided as an interface to transfer the semiconductor substrate between the container SC on the load port module 310 and the load lock chamber 330.

The index module 320 may include a first module housing 321 and the first transferring robot 322. The first transferring robot 322 may be arranged in the first module housing 321, and may transfer the semiconductor substrate between the load port module 310 and the load lock chamber 330. An internal environment of the first module housing 321 may be an atmospheric pressure environment. The first transferring robot 322 may be operated in the atmospheric pressure environment. As shown in FIG. 3, while the equipment 300 includes one first transferring robot 322 in the first module housing 321, the present disclosure is not limited thereto, and the equipment 300 may include multiple first transferring robots 322.

As described above, the load port modules 310 may be provided in the equipment 300. For example, the load port modules may be arranged in a horizontal direction (or a first direction D1). However, the present disclosure is not limited thereto, and the load port modules may be stacked in a vertical direction (or a third direction D3). When the load port modules are stacked in the vertical direction, a front end module may be provided as a vertical stacking equipment front end module (EFEM).

The load lock chamber 330 may function as a buffer chamber between an input port and an output port of the equipment 300. That is, the load lock chamber 330 may temporarily store the unprocessed substrate or the processed substrate between the load port module 310 and the process chamber 350. In an embodiment, the load lock chamber 330 may include a buffer stage for temporarily storing the semiconductor substrate therein.

The load lock chambers 330 may be arranged between the index module 320 and the transfer module 340. For example, two load lock chambers such as the first load lock chamber 330a and the second load lock chamber 330b may be arranged between the index module 320 and the transfer module 340.

The load lock chambers 330 may be arranged in the same direction as the direction in which the load port modules are arranged. The first load lock chamber 330a and the second load lock chamber 330b may be arranged in the same direction as the direction in which the three load port modules 310a, 310b, and 310c are arranged, that is, the horizontal direction (or the first direction D1) between the index module 320 and the transfer module 340. The first load lock chamber 330a and the second load lock chamber 330b may be provided in a mutually symmetric single-layered structure in which they are spaced apart from each other in the horizontal direction. However, the present disclosure is not limited thereto, and the load lock chambers may be arranged in a direction that is different from the direction in which the load port modules are arranged. For example, the first load lock chamber 330a and the second load lock chamber 330b may be arranged in the direction that is different from the direction in which the load port modules 310a, 310b, and 310c are arranged, for example, the vertical direction (or the third direction D3) between the index module 320 and the transfer module 340. The first load lock chamber 330a and the second load lock chamber 330b may have a double-layered structure in which they are spaced apart from each other in the top-to-bottom direction.

One of the first load lock chamber 330a and the second load lock chamber 330b may temporarily store the semiconductor substrate transferred to the transfer module 340 from the index module 320, that is, the unprocessed substrate. The other load lock chamber may temporarily store the semiconductor substrate transferred to the index module 320 from the transfer module 340, that is, the processed substrate. However, without being limited thereto, the first load lock chamber 330a and the second load lock chamber 330b may temporarily store the unprocessed substrate and may temporarily store the processed substrate.

The load lock chamber 330 may change its internal space into one of the vacuum environment and the atmospheric pressure environment using a gate valve. In detail, when the first transferring robot 322 of the index module 320 loads the semiconductor substrate in the load lock chamber 330 or the first transferring robot 322 unloads the semiconductor substrate from the load lock chamber 330, the load lock chamber 330 may form its internal space to be the same as or similar to the internal environment of the index module 320. When a second transferring robot 342 of the transfer module 340 loads the semiconductor substrate in the load lock chamber 330 or the second transferring robot 342 unloads the semiconductor substrate from the load lock chamber 330, the load lock chamber 330 may form its internal space to be the same as or similar to the internal environment of the transfer module 340. By this, the load lock chamber 330 may prevent an internal atmospheric pressure status of the index module 320 or an internal atmospheric pressure status of the transfer module 340 from being changed.

The transfer module 340 may be arranged between the load lock chamber 330 and the process chamber 350, and may be provided as an interface to transfer the semiconductor substrate between the load lock chamber 330 and the process chamber 350.

The transfer module 340 may include a second module housing 341 and the second transferring robot 342. The second transferring robot 342 may be arranged in the second module housing 341, and may transfer the semiconductor substrate between the load lock chamber 330 and the process chamber 350. The internal environment of the second module housing 341 may be provided as a vacuum environment, and the second transferring robot 342 may be operated in the vacuum environment. One second transferring robot 342 may be provided in the second module housing 341, and without being limited thereto, multiple transferring robots 342 may be provided.

The transfer module 340 may be connected to the process chambers 350. To achieve this, the second module housing 341 may include sides, the second transferring robot 342 may freely rotate through the respective sides of the second module housing 341 to load the semiconductor substrate in the process chambers 350 or unload the semiconductor substrate from the process chambers 350.

The process chamber 350 processes the semiconductor substrate. When the unprocessed semiconductor substrate is provided, the process chamber 350 may process the semiconductor substrate, and may provide the processed semiconductor substrate to the load lock chamber 330 through the transfer module 340.

When including the process chambers, the equipment 300 may have a cluster platform. For example, the process chambers may be arranged in a cluster form with respect to the transfer module 340. However, the present disclosure is not limited thereto, and the equipment 300 may have a quad platform when including the process chambers. In some embodiments, the equipment 300 may have an inline platform when including the process chambers. For example, the process chambers may be arranged in an inline scheme with respect to the transfer module 340, and two different process chambers may have a corresponding relationship and may be arranged in series on both sides of the transfer module 340.

The process chamber 350 may be formed of alumite of which a surface is made of an anodizing film, and its interior may have air-tightness. Multiple process chambers 350 may be provided in the equipment 300, and may be spaced apart from each other around the transfer module 340. However, without being limited thereto, a single process chamber 350 may be provided in the equipment 300. The process chamber 350 may have a cylinder shape, and without being limited thereto, it may have other shapes. The equipment 300 may further include a control device. The control device may control operations of the respective modules of the equipment 300. The control device may control the equipment 300 based on the hardware command (CMD_HW) received from the equipment control device 200. For example, the control device may control the first transferring robot 322 or the second transferring robot 342 to transfer the semiconductor substrate, may control changes of the internal environment of the load lock chamber 330, and may control the substrate processing process of the process chamber 350.

The control device may include: a process controller configured with a microprocessor or microcomputer controlling the equipment 300; a keyboard for an operator to input commands to manage the equipment 300; a user interface including a display for visualizing and displaying operation states of the equipment 300; a control program for performing various types of processes executed by the equipment 300 by control of the process controller; a program for performing processes on the respective modules according to various data and processing conditions; and a memory portion for storing processing recipes. The user interface and the memory portion may access the process controller. The processing recipes may be stored in a memory medium of the memory portion, and the memory medium may be a hard disk drive, a Bernoulli box such as a CD-ROM or a DVD, and a semiconductor memory such as a flash memory.

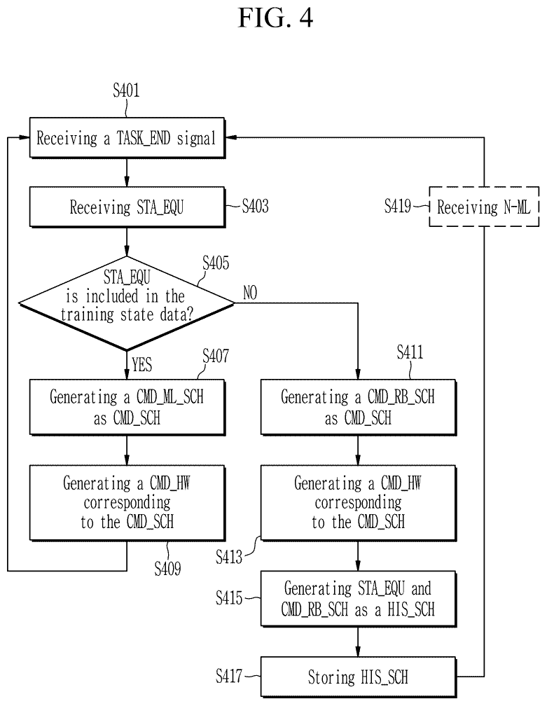

FIG. 4 shows an operation of the semiconductor equipment controlling system 100 including the equipment control device 200 of FIG. 2.

The equipment control device 200 receives a task end signal (TASK_END) (S401).

The equipment control device 200 receives status data (STA_EQU) (S403).

In an embodiment, the scheduling algorithm selector 210 may receive status data (STA_EQU) from the equipment 110. While FIG. 4 shows that the equipment control device 200 sequentially receives the task end signal (TASK_END) and the status data (STA_EQU), the present disclosure is not limited thereto, and the equipment control device 200 may periodically or continuously receive the status data (STA_EQU).

The equipment control device 200 determines whether the status data (STA_EQU) are included in the training data (S405).

In an embodiment, the scheduling algorithm selector 210 may determine whether the status data (STA_EQU) are included in the training data. The training data may be status data for training the neural network model of the learning-based scheduling module 230.

When determining that the status data (STA_EQU) are included in the training data (S405; YES), the equipment control device 200 generates the second scheduling command (CMD_ML_SCH) as the final scheduling command (CMD_SCH) (S407).

In an embodiment, when determining that the status data (STA_EQU) are included in the training data, the scheduling algorithm selector 210 may generate the second enable signal (EN_ML) for enabling the learning-based scheduling module 230. The learning-based scheduling module 230 may determine the second scheduling command (CMD_ML_SCH) that corresponds to the status data (STA_EQU) using the first neural network model in response to receiving the second enable signal (EN_ML). The learning-based scheduling module 230 may output the second scheduling command (CMD_ML_SCH) to the hardware layer 203 as the final scheduling command (CMD_SCH).

The equipment control device 200 may generate a hardware command (CMD_HW) that corresponds to the final scheduling command (CMD_SCH) (S409).

In an embodiment, the hardware layer 203 may convert the received final scheduling command (CMD_SCH) into a hardware command (CMD_HW).

The equipment control device 200 then performs the operation of S401.

When determining that the status data (STA_EQU) are not included in the training data (S405; NO), the equipment control device 200 generates the first scheduling command (CMD_RB_SCH) as the final scheduling command (CMD_SCH) (S411).

In an embodiment, when determining whether the status data (STA_EQU) are not included in the training data, the scheduling algorithm selector 210 may generate the first enable signal (EN_RB) for enabling the rule-based scheduling algorithm 220. The rule-based scheduling algorithm 220 may determine the first scheduling command (CMD_RB_SCH) based on the predetermined scheduling rule in response to receiving the first enable signal (EN_RB). The rule-based scheduling algorithm 220 may output the first scheduling command (CMD_RB_SCH) to the hardware layer 203 as the final scheduling command (CMD_SCH).

The equipment control device 200 may generate a hardware command (CMD_HW) that corresponds to the final scheduling command (CMD_SCH) (S413).

In an embodiment, the hardware layer 203 may convert the transmitted final scheduling command (CMD_SCH) into a hardware command (CMD_HW).

The equipment control device 200 may generate the status data (STA_EQU) and the first scheduling command (CMD_RB_SCH) as the history data (HIS_SCH) (S415).

In an embodiment, the rule-based scheduling algorithm 220 may generate history data (HIS_SCH) including the status data (STA_EQU) and the first scheduling command (CMD_RB_SCH). As described above, the history data (HIS_SCH) may be information on the optimized schedule that corresponds to the training data and the unlearned data.

The equipment control device 200 may store the history data (HIS_SCH) (S417).

In an embodiment, the rule-based scheduling algorithm 220 may store the history data (HIS_SCH) in the main database 205. The equipment control device 200 may transmit the history data (HIS_SCH) stored in the main database 205 to the scheduling learning device 150. The scheduling learning device 150 may update the optimized scheduling model based on the history data (HIS_SCH). The scheduling learning device 150 may generate updated model data (N_ML).

The equipment control device 200 may receive the updated model data (N_ML) (S419).

The learning-based scheduling module 230 may receive the updated model data (N_ML) from the scheduling learning device 150. The learning-based scheduling module 230 may update the neural network model based on the updated model data (N_ML).

The equipment control device 200 then performs the operation of S401.

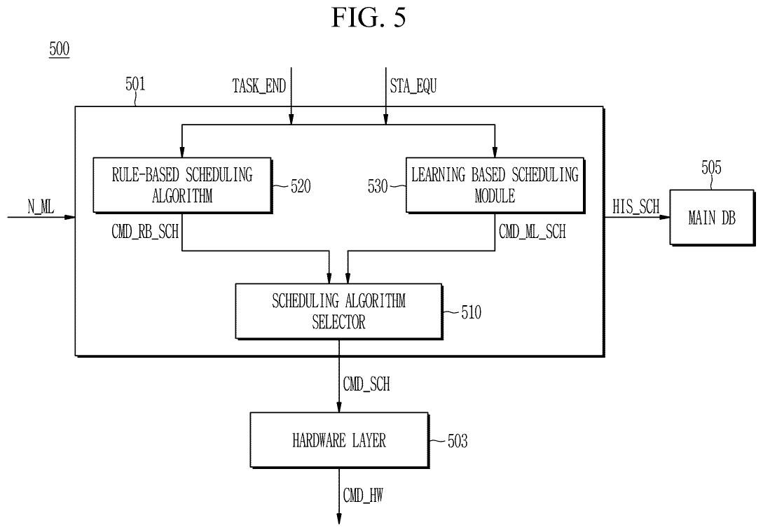

Referring to FIG. 5, the equipment control device 500 may include a scheduling layer 501, a hardware layer 503, and a main database 505.

The scheduling layer 501 may determine the final schedule based on the status data (STA_EQU). In an embodiment, the scheduling layer 501 may determine the final schedule in response to receiving the task end signal (TASK_END). The scheduling layer 501 may generate the final scheduling command (CMD_SCH) based on the final schedule. The scheduling layer 501 may transmit the final scheduling command (CMD_SCH) to the hardware layer 503.

The scheduling layer 501 may include a scheduling algorithm selector 510, a rule-based scheduling algorithm 520, and a learning-based scheduling module 530.

The rule-based scheduling algorithm 520 may determine the schedule to be performed by the equipment 110 based on the predetermined scheduling rule. For example, the rule-based scheduling algorithm 520 may determine the schedule that corresponds to the status data (STA_EQU) transmitted from the equipment 110 based on the scheduling rule. The rule-based scheduling algorithm 520 may generate a first scheduling command (CMD_RB_SCH) that corresponds to the determined schedule.

In an embodiment, the scheduling rule may include information on arbitrary first status data and schedules that respectively correspond to the arbitrary first status data. The scheduling rule may include information on the schedule that corresponds to the first status data indicating a case in which the equipment 110 is abnormally operated.

The rule-based scheduling algorithm 520 may generate the history data (HIS_SCH). The history data (HIS_SCH) may include information on the unlearned data processed by the rule-based scheduling algorithm 520. In an embodiment, the history data (HIS_SCH) may include the unlearned data received by the equipment control device 500 and the schedule determined by the rule-based scheduling algorithm 520 corresponding to the unlearned data. For example, the history data (HIS_SCH) may include status data (STA_EQU) and a first scheduling command (CMD_RB_SCH) that corresponds to the status data (STA_EQU). The rule-based scheduling algorithm 520 may transmit the history data (HIS_SCH) to the main database 505.

The learning-based scheduling module 530 may include a first neural network model trained by the scheduling learning device 150. The learning-based scheduling module 530 may determine the optimized schedule that corresponds to the status data (STA_EQU) using the trained first neural network model. For example, the learning-based scheduling module 530 may determine the optimized schedule using the first neural network model by inputting the status data (STA_EQU) into the first neural network model and obtaining the optimized schedule as output. The learning-based scheduling module 530 may generate a second scheduling command (CMD_ML_SCH) that corresponds to the optimized schedule.

In an embodiment, the learning-based scheduling module 530 may receive the updated model data (N_ML) from the scheduling learning device 150. The updated model data (N_ML) may include data on the optimized scheduling model learned by the scheduling learning device 150 based on the history data (HIS_SCH). For example, the updated model data (N_ML) may include information on the unlearned data included in the history data (HIS_SCH) and the optimized schedule that corresponds to the unlearned data. The learning-based scheduling module 530 may update the first neural network model based on the updated model data (N_ML). The learning-based scheduling module 530 may determine the optimized schedule that corresponds to the status data (STA_EQU) based on the updated first neural network model.

The scheduling algorithm selector 510 may determine whether the status data (STA_EQU) are included in the training data. The training data may be status data learned by the learning-based scheduling module 530. In an embodiment, the scheduling algorithm selector 510 may receive the training data prestored in the main database 505. In some embodiments, the scheduling algorithm selector 510 may pre-store the training data.

In an embodiment, when determining whether the status data (STA_EQU) are not included in the training data, that is, when determining that the status data (STA_EQU) are the unlearned data, the scheduling algorithm selector 510 may determine the first scheduling command (CMD_RB_SCH) as the final scheduling command (CMD_SCH).

In an embodiment, when determining whether the status data (STA_EQU) are included in the training data, the scheduling algorithm selector 510 may determine the second scheduling command (CMD_ML_SCH) as the final scheduling command (CMD_SCH).

The main database 505 may store data for the equipment control device 500 to control the equipment 110. In an embodiment, the main database 505 may store the history data (HIS_SCH). The rule-based scheduling algorithm 520 may transmit the history data (HIS_SCH) stored in the main database 505 to the scheduling learning device 150. In an embodiment, when receiving the updated model data (N_ML), the learning-based scheduling module 530 may store the status data included in the updated model data (N_ML) in the main database 505 as learned data.

In an embodiment, the main database 505 may include a permanent mass storage device such as a random access memory (RAM), a read only memory (ROM), and a disk drive.

The hardware layer 503 may receive the final scheduling command (CMD_SCH) from the scheduling layer 501, and may convert the final scheduling command (CMD_SCH) into a hardware command (CMD_HW). The hardware command (CMD_HW) may control the respective parts of the equipment 110. For example, the hardware command (CMD_HW) may include commands for controlling chambers or arms of transferring robots in the equipment 110, etc. The hardware layer 503 may pre-store a hardware command (CMD_HW) that corresponds to the final scheduling command (CMD_SCH). The hardware layer 503 may control the equipment 110 through the hardware command (CMD_HW).

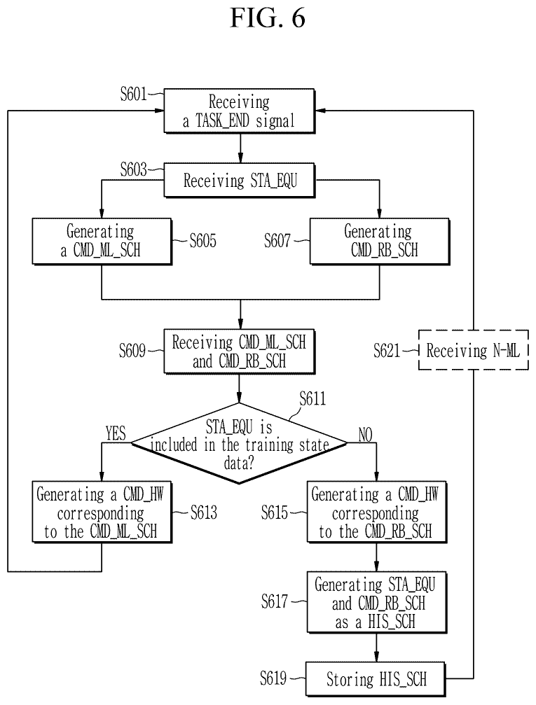

FIG. 6 shows an operation of the semiconductor equipment controlling system 100 including the equipment control device 500 of FIG. 5.

The equipment control device 500 receives a task end signal (TASK_END) (S601).

The equipment control device 500 receives status data (STA_EQU) (S603).

In an embodiment, the scheduling algorithm selector 510 may receive the status data (STA_EQU) from the equipment 110. While FIG. 6 shows that the equipment control device 500 sequentially receives the task end signal (TASK_END) and the status data (STA_EQU), the present disclosure is not limited thereto, and the equipment control device 500 may periodically or continuously receive the status data (STA_EQU).

A second scheduling command (CMD_ML_SCH) is generated (S605).

The learning-based scheduling module 530 may determine the second scheduling command (CMD_ML_SCH) that corresponds to the status data (STA_EQU) using the first neural network model.

A first scheduling command (CMD_RB_SCH) is generated (S607).

The rule-based scheduling algorithm 520 may determine the first scheduling command (CMD_RB_SCH) that corresponds to the status data (STA_EQU) based on the predetermined scheduling rule.

The first scheduling command (CMD_RB_SCH) and the second scheduling command (CMD_ML_SCH) are received (S609).

In an embodiment, the scheduling algorithm selector 510 may receive the first scheduling command (CMD_RB_SCH) and the second scheduling command (CMD_ML_SCH).

The equipment control device 500 may determine whether the status data (STA_EQU) are included in the training data (S611).

In an embodiment, the scheduling algorithm selector 510 may determine whether the status data (STA_EQU) are included in the training data. The training data may be status data used to train the neural network model by the learning-based scheduling module 530.

When determining that the status data (STA_EQU) are included in the training data (S611; YES), the equipment control device 500 determines the second scheduling command (CMD_ML_SCH) as the final scheduling command (CMD_SCH), and generates a hardware command (CMD_HW) that corresponds to the final scheduling command (CMD_SCH) (S613).

In an embodiment, when determining that the status data (STA_EQU) are included in the training data, the scheduling algorithm selector 510 may determine the second scheduling command (CMD_ML_SCH) as the final scheduling command (CMD_SCH). The scheduling algorithm selector 510 may output the second scheduling command (CMD_ML_SCH) to the hardware layer 503 as the final scheduling command (CMD_SCH).

The equipment control device 500 then performs the operation of S601.

When determining that the status data (STA_EQU) are not included in the training data (S611; NO), the equipment control device 500 determines the first scheduling command (CMD_RB_SCH) as the final scheduling command (CMD_SCH) and generates a hardware command (CMD_HW) that corresponds to the final scheduling command (CMD_SCH) (S615).

In an embodiment, when determining that the status data (STA_EQU) are not included in the training data, the scheduling algorithm selector 510 may determine the first scheduling command (CMD_RB_SCH) as the final scheduling command (CMD_SCH). The scheduling algorithm selector 510 may output the first scheduling command (CMD_RB_SCH) to the hardware layer 503 as the final scheduling command (CMD_SCH).

The equipment control device 500 may generate the status data (STA_EQU) and the first scheduling command (CMD_RB_SCH) as the history data (HIS_SCH) (S617).

In an embodiment, the rule-based scheduling algorithm 520 may generate the history data (HIS_SCH) including the status data (STA_EQU) and the first scheduling command (CMD_RB_SCH). As described above, the history data (HIS_SCH) may be information on the unlearned data and the optimized schedule that corresponds to the unlearned data.

The equipment control device 500 may store the history data (HIS_SCH) (S619).

In an embodiment, the rule-based scheduling algorithm 520 may store the history data (HIS_SCH) in the main database 505. The equipment control device 500 may transmit the history data (HIS_SCH) stored in the main database 505 to the scheduling learning device 150. The scheduling learning device 150 may update the optimized scheduling model based on the history data (HIS_SCH). The scheduling learning device 150 may generate the updated model data (N_ML).

The equipment control device 500 may receive the updated model data (N_ML) (S621).

The learning-based scheduling module 530 may receive the updated model data (N_ML) from the scheduling learning device 150. The learning-based scheduling module 530 may update the neural network model based on the updated model data (N_ML).

The equipment control device 500 then performs the operation of S601.

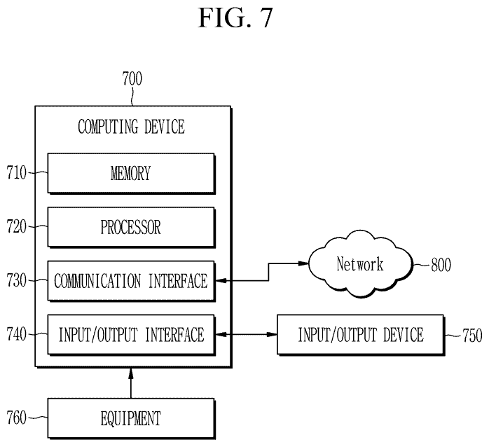

FIG. 7 shows an example of a computing device for implementing a semiconductor equipment controlling system according to an embodiment. The equipment control device 130 of FIG. 1, the equipment control device 200 of FIG. 2, and the equipment control device 500 of FIG. 5 may be realized by the computing device 700 of FIG. 7.

Referring to FIG. 7, the computing device 700 may include a memory 710, a processor 720, a communication interface 730, and an input/output interface 740.

The memory 710 may include a computer-readable recording medium, such as a random access memory (RAM), a read only memory (ROM), and a permanent mass storage device such as a disk drive. The memory 710 may store an operating system and at least one program code. These software components may be loaded on the memory 710 from the computer-readable recording medium separated from the memory 710. The separate computer-readable recording medium may include a computer-readable recording medium such as a hard disk drive, a flash memory, an optical disk, or an external hard disk drive. The software components may be loaded on the memory 710 through the communication interface 730.

The processor 720 may be operatively connected to the memory 710 and the communication interface 730. The processor 720 may process an instruction of the computer program by performing basic arithmetic, logic, and input/output operations. The instruction may be provided to the processor 720 by the memory 710 or the communication interface 730.

In an embodiment, the processor 720 may receive status data indicating a status of the equipment 760 from the equipment 760, and may determine the optimized schedule for controlling the equipment 760 based on the received status data. In an embodiment, the processor 720 may determine the schedule based on the predetermined scheduling rule, and may determine the optimized schedule based on the trained neural network model. The processor 720 may control the equipment 760 based on the determined optimized schedule.

The processor 720 may execute the instructions stored in the memory 710. The processor 720 may control the computing device 700 to execute the operations of the equipment control devices 130, 200, and 500 by executing the instructions stored in the memory 710 according to FIG. 1 to FIG. 6.

The communication interface 730 may provide a function for the computing device 700 to communicate with other devices through the network 800. The communication method is not limited, and may include a short-distance wireless communication between devices as well as a communication method utilizing a communication network (e.g., a mobile communication network, a wired network, a wireless network, or a broadcasting network) included by the network 800. For example, the network 800 may include at least one arbitrary network among the networks such as a personal area network (PAN), a local area network (LAN), a campus area network (CAN), a metropolitan area network (MAN), a wide area network (WAN), a broadband network (BBN), and the internet. The network 800 may include at least one arbitrary network of a network topology including a bus network, a star network, a ring network, a mesh network, a star-bus network, a tree or hierarchical network, and is not limited thereto.

In an embodiment, the computing device 700 may communicate with another computing device through the network 800. The other computing device may include a scheduling learning model. The other computing device may receive status data of the equipment 760 from the computing device 700. In an embodiment, the scheduling learning model may be trained to determine the optimized schedule with the highest yield from among candidate schedules by which the equipment 760 is operable based on the status data received from the computing device 700.

The input/output interface 740 may transmit instructions or data input by a user or the input/output device 750 to other component(s) of the computing device 700. In an embodiment, the input/output device 750 may receive data on the scheduling rule from the user. The input/output interface 740 may transmit data on the scheduling rule input by the input/output device 750 to the processor 720. The input/output interface 740 may output instructions or data received from other component(s) of the computing device 700 to the user or the input/output device 750. For example, the input/output device 750 may include an input device such as a microphone, a keyboard, or a mouse, and an output device such as a display or a speaker.

In prior art, the equipment control device controls the equipment based on the scheduling rule or the neural network model. Hence, when controlling the equipment based on the scheduling rule, the equipment is controlled based on the schedule set by the user irrespective of the optimized schedule of the equipment. When controlling the equipment based on the neural network model, abnormal operations of the equipment are not prevented. Meanwhile, the computing device 700 according to an embodiment may determine the optimized schedule for controlling the equipment 760 based on the neural network model trained by the scheduling rule and under a specific condition to obtain stability. The computing device 700 may determine the optimized schedule of the equipment 760 in real-time without stopping the operation of the equipment 760. Hence, productivity and yield of at least one wafer processed by the equipment 760 may increase.

The embodiments described above may be implemented in a form of a computer program that may be executed through various components on the computer, and the program may be recorded on a non-transitory computer readable medium. The medium may include a magnetic media such as a hard disk drive, a floppy disk, and a magnetic tape, an optical recording media such as a CD-ROM and a DVD, and a hardware device specifically configured to store and execute a program command such as a ROM, a RAM, or a flash memory.

The stages constituting the method according to the embodiments may be performed in an appropriate order unless explicitly stated or contradicted by the order. The present disclosure is not necessarily limited to the described order of steps.

The use of all examples or illustrative terms (for example, etc.) in the present disclosure is for describing the present disclosure in detail, and the scope of the present disclosure is not limited by examples or illustrative terms unless limited by the claims. In addition, a person skilled in the art may recognize that various modifications, combinations, and changes may be configured according to design conditions and factors within the scope of the appended claims or their equivalents.

While this disclosure has been described in connection with what is presently considered to be practical embodiments, it is to be understood that the disclosure is not limited to the disclosed embodiments, but, on the contrary, is intended to cover various modifications and equivalent arrangements included within the scope of the appended claims.

What is claimed is:

1. A semiconductor equipment controlling system, comprising:
a scheduling algorithm selector configured to:
receive status data indicating a status of equipment;
determine whether the status data is included in training data, wherein the training data includes data for training a learning-based scheduling module;
generate a first enable signal in response to the status data not being included in the training data; and
generate a second enable signal in response to the status data being included in the training data;
a rule-based scheduling algorithm configured to determine a first schedule corresponding to the status data based on a predetermined scheduling rule in response to receiving the first enable signal;
the learning-based scheduling module including a first neural network model, the learning-based scheduling module configured to determine a second schedule corresponding to the status data using the first neural network model in response to receiving the second enable signal; and
a hardware layer configured to generate a hardware command for controlling the equipment based on a final determined schedule, wherein:
the final determined schedule includes the first schedule if the first enable signal is generated; and
the final determined schedule includes the second schedule if the second enable signal is generated.

2. The semiconductor equipment controlling system of claim 1, wherein the rule-based scheduling algorithm is further configured to generate history data including the status data and the first schedule.

3. The semiconductor equipment controlling system of claim 2, further comprising:
a scheduling learning device including a second neural network model, the training data, the history data, and a third schedule corresponding to the training data, wherein the scheduling learning device is configured to generate an optimized scheduling model by training the second neural network model based on the training data and the history data.

4. The semiconductor equipment controlling system of claim 3, wherein:
the scheduling learning device includes a simulation module for simulating an operation of the equipment; and
the simulation module is configured to:
generate a plurality of candidate schedules for the equipment based on the history data; and
determine a first candidate schedule as an optimized schedule from among the plurality of candidate schedules, in which at least one wafer on which the equipment performs a task has a highest yield.

5. The semiconductor equipment controlling system of claim 4, wherein the scheduling learning device is further configured to generate updated model data including the first candidate schedule.

6. The semiconductor equipment controlling system of claim 5, wherein the learning-based scheduling module is further configured to:
update the first neural network model based on the updated model data;
update the training data to include the history data; and
determine the first candidate schedule as the second schedule based on the updated first neural network model.

7. The semiconductor equipment controlling system of claim 1, wherein the scheduling rule includes at least one status data for the equipment and a schedule predetermined corresponding to each of the at least one status data.

8. The semiconductor equipment controlling system of claim 7, wherein:
the first neural network model is trained based on the training data to output an optimized schedule for the equipment in response to an input of status data, and the training data includes a portion of at least one status data in the scheduling rule.

9. The semiconductor equipment controlling system of claim 1, wherein the status data includes at least one of hardware data of the equipment, wafer status data for at least one wafer processed by the equipment, and task data for the at least one wafer.

10. A semiconductor equipment controlling system, comprising:
a rule-based scheduling algorithm configured to:
receive status data indicating a status of equipment; and
generate a first scheduling command corresponding to the status data based on a predetermined scheduling rule;
a learning-based scheduling module configured to:
receive the status data; and
generate a second scheduling command corresponding to the status data using a first neural network model trained on training data;
a scheduling algorithm selector configured to:
determine whether the status data is included in the training data;
determine the first scheduling command as a final scheduling command in response to the status data not being included in the training data; and
determine the second scheduling command as the final scheduling command in response to the status data being included in the training data; and
a hardware layer configured to convert the final scheduling command into a hardware command for controlling the equipment.

11. The semiconductor equipment controlling system of claim 10, wherein:
the scheduling rule includes at least one status data for the equipment and a schedule predetermined corresponding to each of the at least one status data; and
the first scheduling command indicates a schedule predetermined corresponding to the status data.

12. The semiconductor equipment controlling system of claim 10, wherein the rule-based scheduling algorithm is further configured to generate history data including the status data and the first schedule.

13. The semiconductor equipment controlling system of claim 12, further comprising:
a scheduling learning device including a second neural network model, the training data, the history data, and a third schedule corresponding to the training data, wherein the scheduling learning device is configured to generate an optimized scheduling model by training the second neural network model based on the training data and the history data.

14. The semiconductor equipment controlling system of claim 13, wherein:
the scheduling learning device includes a simulation module for simulating an operation of the equipment; and
the simulation module is configured to:
generate a plurality of candidate schedules for the equipment based on the history data; and
determine a first candidate schedule as an optimized schedule from among the plurality of candidate schedules, in which at least one wafer on which the equipment performs a task has a highest yield.

15. The semiconductor equipment controlling system of claim 14, wherein:
the scheduling learning device is further configured to generate an updated model data including the first candidate schedule; and
the learning-based scheduling module is further configured to:
update the first neural network model based on the updated model data;
update the training data to include the history data; and
determine the first candidate schedule as the second schedule based on the updated first neural network model.

16. The semiconductor equipment controlling system of claim 10, wherein:
the first neural network model is trained based on the training data to output an optimized schedule for the equipment in response to an input of status data;
the scheduling rule includes at least one status data for the equipment and a schedule predetermined corresponding to each of the at least one status data; and
the training data includes a portion of the at least one status data in the scheduling rule.

17. A semiconductor equipment controlling system, comprising:
equipment configured to perform a task for at least one wafer and generate status data indicating a status while performing the task;
an equipment control device configured to:
receive the status data;
determine a final schedule based on whether the status data are included in training data, wherein the training data includes data for training a learning-based scheduling module; and
control the equipment based on the final schedule, wherein:
the final schedule includes a first schedule determined based on a predetermined scheduling rule in response to the status data not being included in the training data; and
the final schedule includes a second schedule determined using a trained first neural network model in response to the status data being included in the training data; and
a scheduling learning device including a second neural network model, the training data, history data, and a third schedule corresponding to the training data, wherein the scheduling learning device is configured to generate an optimized scheduling model by training the second neural network model based on the training data and the history data.

18. The semiconductor equipment controlling system of claim 17, wherein:
the equipment is further configured to:
generate a task end signal in response to performance of the task ending; and
determine the final schedule in response to receiving the task end signal.

19. The semiconductor equipment controlling system of claim 18, wherein:
the equipment control device is further configured to generate the history data and the first schedule; and
the scheduling learning device includes a simulation module configured to:
simulate an operation of the equipment;
generate a plurality of candidate schedules for the equipment based on status data in the history data; and
determine a first candidate schedule as an optimized schedule from among the plurality of candidate schedules, in which the at least one wafer has a highest yield.

20. The semiconductor equipment controlling system of claim 19, wherein the scheduling learning device is further configured to:
generate updated model data including the first candidate schedule;
update the first neural network model based on the updated model data;
update the training data to include the history data; and
determine the first candidate schedule as the second schedule based on the updated first neural network model.
